(19) United States
(12) Patent Application Publication
(10) Pub. No.: US 2003/0054608 A1
(43) Pub. Date: Mar. 20, 2003

(54) Method for forming shallow trench isolation in semiconductor device

(75) Inventors: Kuo-Shu Tseng, Hsinchu Hsien (TW); Yu-Tai Chen, Hsinchu Hsien (TW); Chyei-Jer Hsieh, Tainan (TW); Nai-Wen Chang, Changhua Hsien (TW)

Correspondence Address: INTELLECTUAL PROPERTY SOLUTIONS, INCORPORATED, 5717 COLFAX AVENUE, ALEXANDRIA, VA, 22311, US

(73) Assignee: VANGUARD INTERNATIONAL SEMICONDUCTOR CORPORATION, Hsinchu (TW)

(21) Appl. No.: 09/953,222

(22) Filed: Sep. 17, 2001

(51) Int. Cl. H01L 21/336; H01L 21/76

(52) U.S. Cl. 438/257; 438/296; 438/424

(57) ABSTRACT

The present invention discloses a method for forming shallow trench isolation in a semiconductor device, particularly a nonvolatile memory device. A dielectric layer, an amorphous silicon layer, and a mask layer are sequentially formed over a substrate. Isolation trenches are etched in the substrate through the layers. An oxide layer is thermally grown lining the sidewalls of the amorphous silicon layer and the trenches. Due to the lower oxidation rate of amorphous silicon, the liner oxide layer is thinner at the position lining the amorphous silicon layer than at the position lining the trench. The trenches are filled with an isolation layer to form shallow trench isolation (STI) structures. After removing the mask layer, the amorphous silicon layer can be converted into a polysilicon layer to serve as a floating gate for a nonvolatile memory device.

### BACKGROUND OF THE INVENTION

1. Field of the Invention

The present invention relates in general to a method for forming shallow trench isolation (STI) in a semiconductor device. More particularly, it relates to a method for forming STI in a nonvolatile memory device such as an EPROM (erasable programmable read only memory), EEPROM (electrically erasable programmable read only memory) or a flash memory.

2. Description of the Related Arts

High-density nonvolatile memory devices have been receiving much attention for application in many fields. One of the most important factors is the low cost of the reduced size of each memory cell. However, it is very difficult to shrink cell size in the fabrication of nonvolatile memory cells when the conventional local oxidation (LOCOS) isolation technique is used. The isolation structure formed by this technique has very large dimensions and thus limits the miniaturization of the memory cells.

Another isolation technique called shallow trench isolation (STI) has been introduced to the fabrication of nonvolatile memory devices to reduce the cell size. Conventional field oxides are replaced by STI structures so that device integration can be effectively improved. However, as the isolation pitch scales down, a phenomenon called “inverse narrow channel effect” becomes more critical.

In a trench isolation structure, an electric field is concentrated in the proximity of the edge of the trench isolation when a voltage of the level of approximately the threshold value is applied to the gate electrode, whereby a parasitic channel is formed in the proximity of the trench isolation edge. Current will flow through the parasitic channel formed at the sidewall of the trench to result in a lower threshold voltage. This phenomenon, where the threshold voltage is reduced as the channel width becomes smaller, is called an inverse narrow channel effect.

This inverse narrow channel effect has become a significant problem in semiconductor devices including trench isolation structure, since it causes variation in the threshold voltage, which in turn induces degradation of the subthreshold characteristics.

On the other hand, as component dimensions continue to shrink, the surface area of floating gates also shrinks. This leads directly to a decrease in capacitance of the effective capacitor formed between the floating gate layer and the control gate layer. This decrease in effective capacitance results in a reduction of the capacitive coupling ratio, a parameter that describes the coupling to floating gate of the voltage applied to control gate. The poorly-coupled voltage to floating gate limits the programming and access speed characteristics of the memory device.

The capacitive coupling ratio Cp is defined by:

$$Cp = \frac{Ccf}{Ccf + Cfs}$$

where Ccf is capacitance between the control gate and the floating gate; and Cfs is capacitance between the floating gate and the semiconductor substrate.

In order to gain programming and access speeds in nonvolatile memories, many attempts have been made to increase the coupling ratio. It can be understood from the above equation that when the capacitance Ccf between the control gate and the floating gate increases, the coupling ratio Cp increases. Alternatively, the coupling ratio can be increased by reducing the capacitance Cfs between the floating gate and the semiconductor substrate. This can be accomplished by reducing the capacitor area between the floating gate and substrate.

The preset invention aims to the suppress the inverse narrow channel effect and to increase the capacitive coupling ratio.

### SUMMARY OF THE INVENTION

An object of the invention is to provide a method for forming shallow trench isolation in a semiconductor device, wherein the inverse narrow channel effect is avoided.

Another object of the invention is to provide a method for fabricating a nonvolatile memory device with shallow trench isolation and an increased capacitive coupling ratio.

According to an aspect of the invention, there is provided a method for forming shallow trench isolation, which comprises the steps of: forming a dielectric layer and an amorphous silicon layer over a semiconductor substrate; forming a mask layer over the amorphous silicon layer; patterning the mask layer, the amorphous silicon layer, the dielectric layer, and the substrate to form a trench in the substrate; growing a thermal oxide layer lining the sidewalls of the amorphous silicon layer and the trench, the liner oxide layer being thinner at the position lining the amorphous silicon layer than at the position Lining the trench; filling the trench with an isolation layer to form a shallow trench isolation (STI) structure; and removing the mask layer.

According to another aspect of the invention, there is provided a method for fabricating a nonvolatile memory device, which comprises the steps of: forming a tunnel dielectric layer and an amorphous silicon layer over a substrate; forming a mask layer over the amorphous silicon layer; patterning the mask layer, the amorphous silicon layer, the tunnel dielectric layer, and the substrate to form a trench in the substrate; growing a thermal oxide layer lining the sidewalls of the amorphous silicon layer and the trench, the liner oxide layer thinner at the position lining the amorphous silicon layer than at the position lining the trench; filling the trench with an isolation layer to form a shallow trench isolation (STI) structure; removing the mask layer; and sequentially forming an inter-gate dielectric layer and a control gate layer over the substrate, and converting the amorphous silicon layer into a polysilicon layer serving as a floating gate.

### BRIEF DESCRIPTION OF THE DRAWINGS

The above and other objects, features, and advantages of the present invention will become apparent from the following detailed description of preferred embodiments of the invention explained with reference to the accompanying drawings, in which:

FIGS. 1 to 8 are cross-sections illustrating the steps for fabricating shallow trench isolation and a nonvolatile memory device according to a preferred embodiment of the invention.

### DETAILED DESCRIPTION OF THE INVENTION

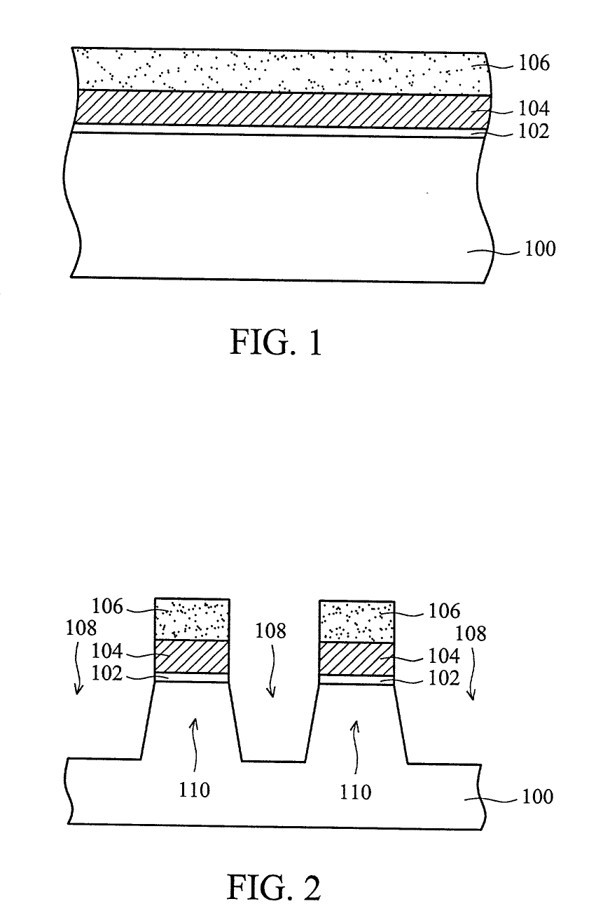

Referring to FIG. 1, a single crystal silicon substrate 100 with a <100>crystallographic orientation is provided. A silicon oxide layer 102 is formed on the surface of the substrate 100 to serve as a pad oxide or as a tunnel oxide for a later nonvolatile memory. The thickness of this oxide layer 102 is about 50 to 350 Å. A suitable method to form the oxide layer 102 can be a thermal oxidation at a temperature of about 750° C. to 950° C., or a low pressure chemical vapor deposition (LPCVD) at a temperature of about 400° .C to 800° C.

Next, as a main feature and a key aspect of the present invention, an amorphous silicon (α-Si) layer 104 is formed over the oxide layer 102 through methods including but not limited to Chemical Vapor Deposition (CVD) methods employing suitable silicon source materials, preferably formed through an LPCVD method employing silane (SiH₄) as a silicon source material at a temperature below 550° C. As will become apparent, the amorphous silicon is formed to serve as a floating gate layer as well as a buffered mask layer. Thus, the amorphous silicon layer 104 is preferably doped with an impurity such as phosphorus. Doping can occur using POCl₃ diffusion, in-situ doping techniques, and implantation techniques.

Next, a mask layer 106 (etch mask or CMP mask) is formed on the amorphous silicon layer 104. The mask layer is preferably composed of silicon nitride (SiN), which can be formed by reacting dichlorosilane (SiCl₂H₂) with ammonia (NH₃) through an LPCVD process.

Referring now to FIG. 2, the mask layer 106, the amorphous silicon layer 104, and the oxide layer 102 together serve as a stacked mask for defining isolation trenches 108 in the substrate 100. The stacked mask is dry etched using a photoresist pattern as an etching mask which protects all areas on which active devices will later be formed. The etching is further carried into the substrate 100 to form trenches 108 which define active regions 110 and isolation areas. The photoresist pattern is then removed.

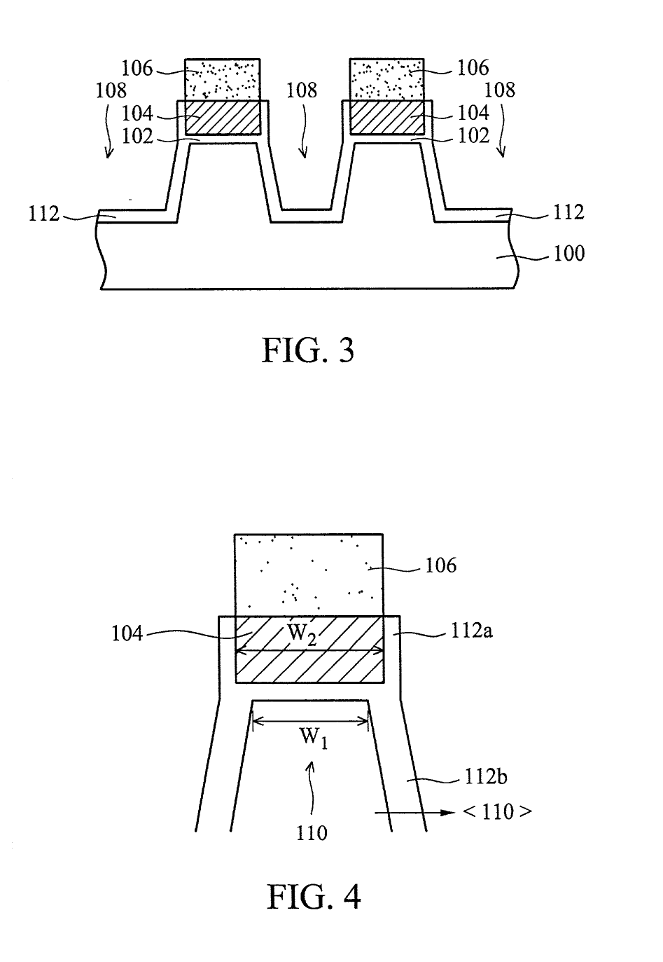

Next, referring to FIG. 3, a thermal oxidation process is performed at a temperature between about 700° C. to 1100° C. and continued for a period from about 20 to 120 seconds. In the thermal oxidation, the sidewall surfaces of the silicon trenches 108 and the amorphous silicon layer 104 are oxidized to form an oxide liner 112. FIG. 4 is a partially enlarged view of FIG. 3, which illustrates the oxide liner 112 lining the sidewalls of the trench 108 and the amorphous silicon layer 104. As shown in FIG. 4, the oxide liner 112 has a thinner portion 112a over the amorphous silicon layer 104 and a thicker portion 112a over the trench 108. This is because the oxidation rate of amorphous silicon is lower than that of silicon with [110] orientation in silicon trench. Less silicon is consumed in the amorphous silicon layer 104 than in the silicon substrate 100.

As a result, the amorphous silicon layer 104, later to be formed into a floating gate, has a larger bottom surface area relative to the active region 110, and as illustrated in the cross-sectional view, the amorphous silicon layer 104 has a width W2 broader than the width W1 of the active region 110. The reduction of the active area 110 relative to the floating gate results in a decrease of the capacitance Cfs between the floating gate and the substrate, and therefore increases the coupling ratio. Furthermore, it is assured that the floating gate can completely cover the underlying active region 110 to provide better device reliability and higher programming and access speed.

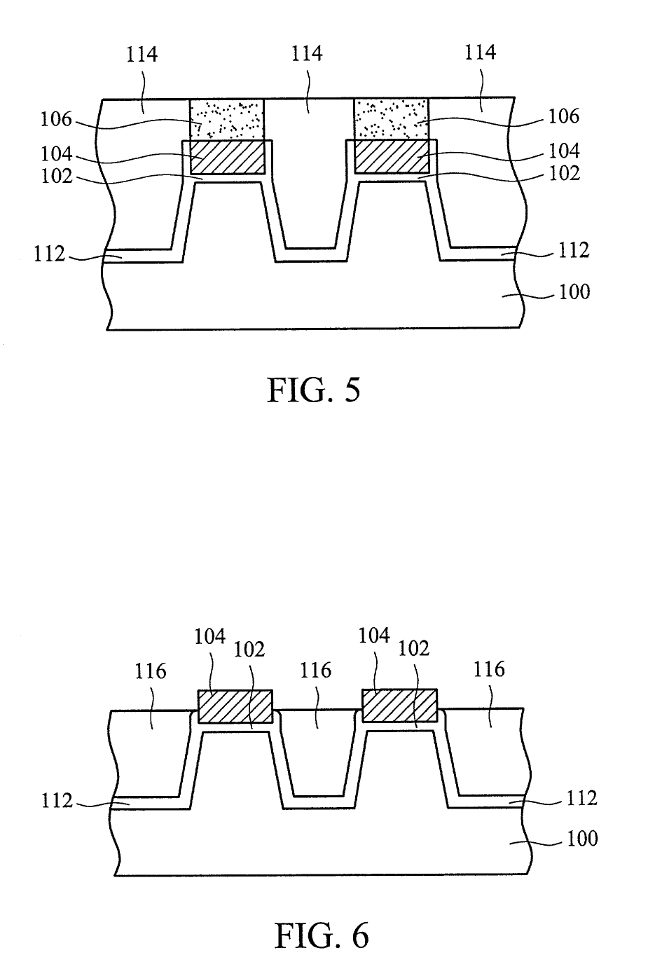

Referring to FIG. 5, an isolation oxide layer 114 is deposited using the method of high density plasma (HDP) deposition or LPCVD to overfill the trenches 108. Then, a chemical-mechanical polishing (CMP) process is performed to planarize the isolation oxide layer 114 using the mask layer 106 as a polishing stop. The isolation layer 114 can also be planarized by an etch back or other suitable planarization technique.

Referring to FIG. 6, the isolation oxide layer 114 and the oxide liner 112 are etched back to expose an upper portion of the amorphous silicon layer 104 to result in a shallow trench isolation (STI) structure 116. This etching step can be performed by either dry etching or wet etching. After this, the mask layer 106 is removed, preferably by a selective etch.

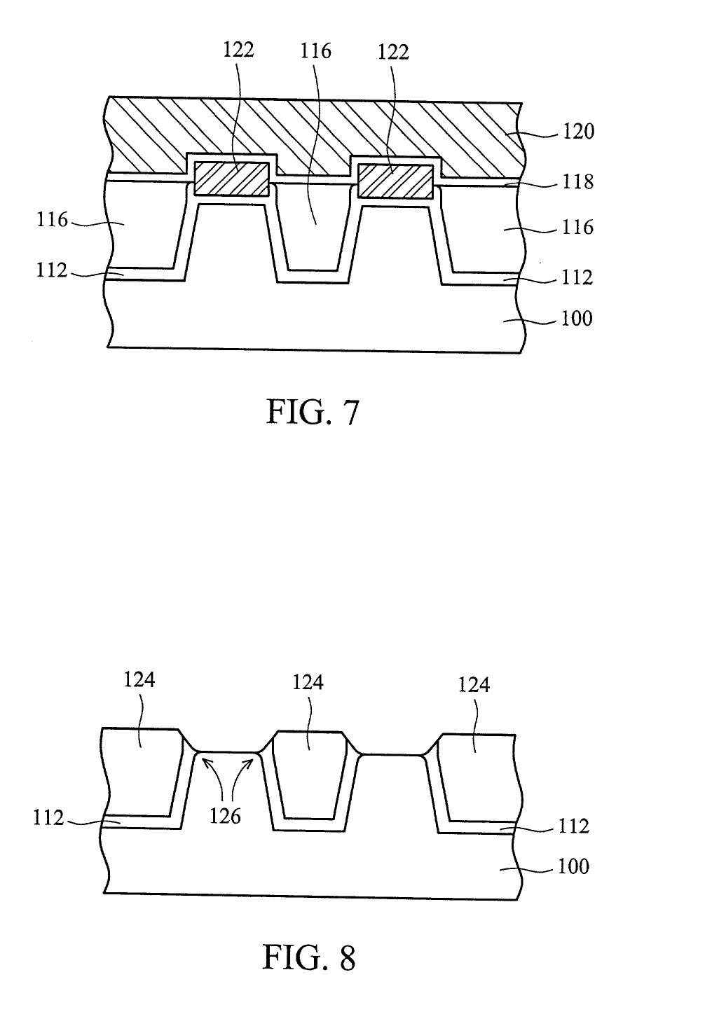

Referring to FIG. 7, an inter-gate dielectric layer 118 is deposited to cover the STI structure 116 and the amorphous silicon layer 104. The inter-gate dielectric layer 120 is typically oxide/nitride/oxide (ONO), nitride/oxide (NO), or Ta₂O₅. Next, a control gate layer 120 is formed on the inter-gate dielectric layer 118. The control gate layer 120 is typically doped polysilicon or polycide. As another key aspect of the present invention, it is preferable that the amorphous silicon layer 104 is converted into polysilicon serving as a floating gate 122 during the deposition of the control gate layer 120. Accordingly, the control gate layer 120 is preferably deposited at a temperature not lower than 550° C. The polysilicon thus formed has a smaller grain size than that directly deposited by CVD methods. Finally, a masking and etching process is performed to define a control gate from the control gate layer 122, thereby forming a memory device.

According to another embodiment of the invention for fabricating shallow trench isolation, the mask layer 106 and the amorphous silicon layer 104 are stripped after planarizing the isolation layer 114. Then the pad oxide layer 102 is removed by diluted HF solution. This results in the STI structure 124 with the small bird's beak 126 as shown in FIG. 8. For the conventional nitride/oxide mask, the oxide at the isolation edge was recessed at this process step. However, in the present invention, the small bird's beak still remained by the sidewall oxide 112 a on the amorphous silicon layer 104. As described in the article of “Advanced Shallow Trench Isolation to Suppress the Inverse Narrow Channel Effects,” Symposium on VLSI Technology, p 178, 2000, the small bird's beak can effectively suppress the inverse narrow channel effect. In addition, the present invention using amorphous silicon has an advantage over the method using polysilicon in the foregoing article. The amorphous silicon generates less stress than polysilicon does, thereby providing a more reliable process.

The present invention provides the following advantages:

1. The amorphous silicon layer provides lower stress performance than poly-crystalline silicon.

2. The inverse narrow width effect can be suppressed to provide better device performance.

3. The amorphous silicon can be converted into polysilicon to serve as a floating gate for a nonvolatile memory device. The polysilicon thus obtained has smaller grain size than that directly deposited by Chemical Vapor Deposition methods.

4. The oxidation rate of amorphous silicon is lower than that of silicon with [110] orientation in silicon trench. As a result, the floating gate can completely cover the underlying active region to provide better device reliability and higher programming and access speed.

5. The capacitive coupling ratio of the memory device is increased by reducing the overlap area between the floating gate and the substrate.

While the invention has been particularly shown and described with reference to the preferred embodiment thereof, it will be understood by those skilled in the art that various changes in form and details may be made without departing from the spirit and scope of the invention.

What is claimed is:

1. A method for forming a shallow trench isolation structure for a semiconductor device, comprising the steps of:
forming a dielectric layer and an amorphous silicon layer over a semiconductor substrate;
forming a mask layer over the amorphous silicon layer;
patterning the mask layer, the amorphous silicon layer, the dielectric layer, and the substrate to form a trench in the substrate;
growing a thermal oxide layer lining the sidewalls of the amorphous silicon layer and the trench, the thermal oxide layer being thinner at the position lining the amorphous silicon layer than at the position lining the trench; and
filling the trench with an isolation layer to form a shallow trench isolation (STI) structure.

2. The method as claimed in claim 1, wherein the semiconductor substrate is a silicon substrate.

3. The method as claimed in claim 1, wherein the dielectric layer comprises silicon oxide.

4. The method as claimed in claim 1, wherein the forming the amorphous silicon layer is accomplished by a low pressure chemical vapor deposition (LPCVD) process at a temperature below about 550° C.

5. The method as claimed in claim 1, wherein the mask layer comprises silicon nitride.

6. The method as claimed in claim 1, wherein the growing of the thermal oxide layer is accomplished by thermal growth at a temperature between about 700° C. to 1100° C.

7. The method as claimed in claim 1, which further includes planarizing the STI structure using a chemical-mechanical polish or etch back process.

8. The method as claimed in claim 1, which further includes removing the mask layer.

9. The method as claimed in claim 8, which further includes removing the amorphous silicon layer and the dielectric layer.

10. A method for fabricating a nonvolatile memory device with shallow trench isolation, comprising the steps of:
forming a tunnel dielectric layer and an amorphous silicon layer over a substrate;
forming a mask layer over the amorphous silicon layer;
patterning the mask layer, the amorphous silicon layer, the tunnel dielectric layer, and the substrate to form a trench in the substrate;
growing a thermal oxide layer lining the sidewalls of the amorphous silicon layer and the trench, the thermal oxide layer being thinner at the position lining the amorphous silicon layer than at the position lining the trench;
filling the trench with an isolation layer to form a shallow trench isolation (STI) structure;
removing the mask layer; and
sequentially forming an inter-gate dielectric layer and a control gate layer over the substrate, and converting the amorphous silicon layer into a polysilicon layer for serving as a floating gate.

11. The method as claimed in claim 10, wherein the semiconductor substrate is a silicon substrate.

12. The method as claimed in claim 10, wherein the tunnel dielectric layer comprises silicon oxide.

13. The method as claimed in claim 10, wherein the forming the amorphous silicon layer is accomplished by a low pressure chemical vapor deposition (LPCVD) process at a temperature below about 550° C.

14. The method as claimed in claim 10, wherein the mask layer comprises silicon nitride.

15. The method as claimed in claim 10, wherein the growing the thermal oxide layer is accomplished by thermal growth at a temperature between about 700° C. to 1100° C.

16. The method as claimed in claim 10, which further includes planarizing the STI structure using a chemical-mechanical polish or etch back process.

17. The method as claimed in claim 10, wherein the trench defines active regions in the substrate, and the floating gate has a larger bottom surface area relative to the active regions.
